(19) United States
(12) Patent Application Publication
(10) Pub. No.: US 2013/0288420 A1
(43) Pub. Date: Oct. 31, 2013

(54) FABRICATING METHOD OF SEMICONDUCTOR DEVICE

(71) Applicant: SAMSUNG ELECTRONICS CO., LTD., Suwon-si (KR)

(72) Inventor: Yun-Ki LEE, Seoul (KR)

(73) Assignee: SAMSUNG ELECTRONICS CO., LTD., Suwon-Si (KR)

(21) Appl. No.: 13/800,569

(22) Filed: Mar. 13, 2013

(30) Foreign Application Priority Data
Apr. 25, 2012 (KR) 10-2012-0043276

(51) Int. Cl. H01L 31/18

(52) U.S. Cl. CPC H01L 31/1864
USPC 438/70; 438/69

(57) ABSTRACT

A method of making a semiconductor device includes forming wiring on a first surface of a first substrate, removing a portion of a second surface of the first substrate to reduce a thickness of the first substrate, forming an oxide film on the second surface of the first substrate based on an oxidation process performed within a temperature range, and removing the oxide film. The temperature range may be below a melting temperature of the wiring, and the oxide film is formed to a depth that includes one or more defects below the second surface of the first substrate. Removal of the oxide film results in removing a portion of the first substrate that includes the one or more effects.

### CROSS-REFERENCE TO RELATED APPLICATION

This application claims priority from Korean Patent Application No. 10-2012-0043276 filed on Apr. 25, 2012 in the Korean Intellectual Property Office, and all the benefits accruing therefrom under 35 U.S.C. 119, the contents of which in its entirety are herein incorporated by reference.

### BACKGROUND

1. Technical Field

The present inventive concept relates to semiconductor devices.

2. Description of the Related Art

An image sensor converts an optical image into electric signals. In recent years, with the development of the communication and computer industries, there has been an increasing demand for high-performance image sensors used in various devices including, for example, digital cameras, camcorders, personal communication systems (PCS), game devices, security cameras, medical micro-cameras, and robots.

A metal oxide semiconductor (MOS) image sensor can be driven by a simple driving method and can be implemented by using various scanning methods. In the MOS image sensor, since a signal processing circuit can be integrated on a single chip, it is possible to achieve the miniaturization of a product. Further, since the MOS processing technologies are compatible, manufacturing costs can be reduced. In addition, since the power consumption is very low, it can be easily applied to a product with limited battery capacity. Accordingly, technological development accompanied by achievement of high resolution is sharply increasing the use of MOS image sensors. However, if light is applied to the MOS image sensor from the front direction, since a portion of light is absorbed or lost while passing through a thick interlayer insulating film, the amount of light condensed is small.

Further, red light having a large wavelength is severely refracted as it passes through the thick interlayer insulating film. As a result, optical crosstalk may occur.

Thus, a backside-illuminated MOS image sensor which receives light from the rear direction has been developed. However, the backside-illuminated MOS image sensor may have poor dark characteristics.

### SUMMARY

One or more embodiments described herein relate to a fabricating method a semiconductor device with improved dark characteristics.

According to one embodiment, a fabricating method of a semiconductor device comprises: forming a multilayer metal wiring on one surface of a substrate; removing a portion of the other surface of the substrate to reduce a thickness of the substrate; forming an oxide film on the other surface of the substrate through low-temperature oxidation; and removing the oxide film. According to another embodiment, a fabricating method of a semiconductor device comprises: forming a multilayer metal wiring on one surface of a substrate; removing a portion of the other surface of the substrate to reduce a thickness of the substrate; forming a hafnium oxide film on the other surface of the substrate through low-temperature oxidation using a plasma; and removing the hafnium oxide film through an etching process.

According to another embodiment, a method of fabricating a semiconductor device includes forming wiring on a first surface of a first substrate; removing a portion of a second surface of the first substrate to reduce a thickness of the first substrate; forming an oxide film on the second surface of the first substrate based on an oxidation process performed within a temperature range; and removing the oxide film. The temperature range may be below a melting temperature of the wiring.

The oxide film may be formed to a depth that includes one or more defects below the second surface of the first substrate, so that removal of the oxide film includes removes a portion of the first substrate that includes the one or more effects. The oxide film is formed to a depth, for example, ranging substantially from 50 Å to 150 Å or to a shallower or greater depth which includes the defects.

The oxidation process is performed may be performed using a plasma and/or may be performed using oxygen or ozone radicals. The oxide film may include at least one of a hafnium oxide film, an aluminum oxide film, a zirconium oxide film, a tantalum oxide film, a titan oxide film, a ruthenium oxide film, an iridium oxide film, a yttrium oxide film, or an oxynitride film.

The method may further include attaching the first substrate to a second substrate before removing a portion of the second surface of the first substrate. Also, removing a portion of the second surface of the first substrate comprises at least one of mechanical grinding, polishing, CMP, wet etching or dry etching. Removing the oxide film may comprise removing the oxide film through an etching process.

After removing the oxide film, the method may include injecting impurities into the second surface of the first substrate, and performing an annealing operation to activate the impurities, wherein the impurities are of a type for preventing flow of a dark current.

The method may also include forming one or more photodiodes facing the first surface of the first substrate, wherein the first substrate is a transparent substrate to allow light to pass to the one or more photodiodes.

The method may also include forming one or more microlenses over the second surface of the first substrate, wherein the one or more microlenses are in substantial alignment with respective ones of the one or more photodiodes.

The method may also include forming one or more color filters over the second surface of the first substrate, wherein the one or more color filters are located between the one or more microlenses and the one or more photodiodes.

According to another embodiment, a method of making a semiconductor device comprises forming wiring on a first surface of a first substrate; removing a portion of a second surface of the first substrate to reduce a thickness of the first substrate; forming a hafnium oxide film on the second surface of the substrate based on oxidation process using a plasma; and removing the hafnium oxide film based on an etching process. The oxidation process may be performed using oxygen or ozone radicals.

The hafnium oxide film may be formed to a depth, for example, ranging substantially from 50 Å to 150 Å or to a lesser or greater depth that includes one or more defects under the second surface of the first substrate.

Removing a portion of the second surface of the first substrate may comprise at least one of mechanical grinding, polishing, CMP, wet etching or dry etching. Also, after removing the hafnium oxide film, the method may include injecting impurities into the second surface of the first substrate, and performing an annealing operation to activate the impurities, wherein the impurities are of a type for preventing flow of a dark current.

The method may also include forming a photodiode facing the first surface of the first substrate, and forming a microlens over the second surface of the first substrate, wherein the first substrate is a transparent substrate to allow light to pass to the photodiode and wherein the microlens is in substantial alignment with the one or more photodiode.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram of one embodiment of a semiconductor device.

FIG. 2 is an equivalent circuit of an APS array of FIG. 1.

FIGS. 3 to 13 are diagrams showing intermediate steps corresponding to one embodiment of a fabricating method of a semiconductor device.

FIG. 14 is a schematic block diagram showing one embodiment of a processor-based system.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

In the drawings, it is understood that the thicknesses of layers and regions may be exaggerated for clarity. It will also be understood that when a layer is referred to as being “on” another layer or substrate, it can be directly on the other layer or substrate or intervening layers may also be present. Like reference numerals in the drawings denote like elements, and thus their description will not be repeated. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

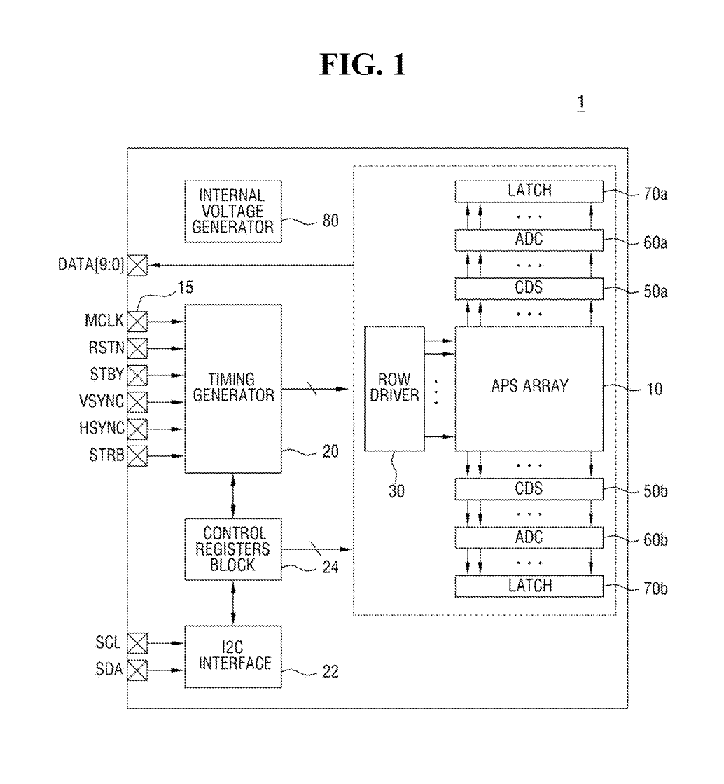

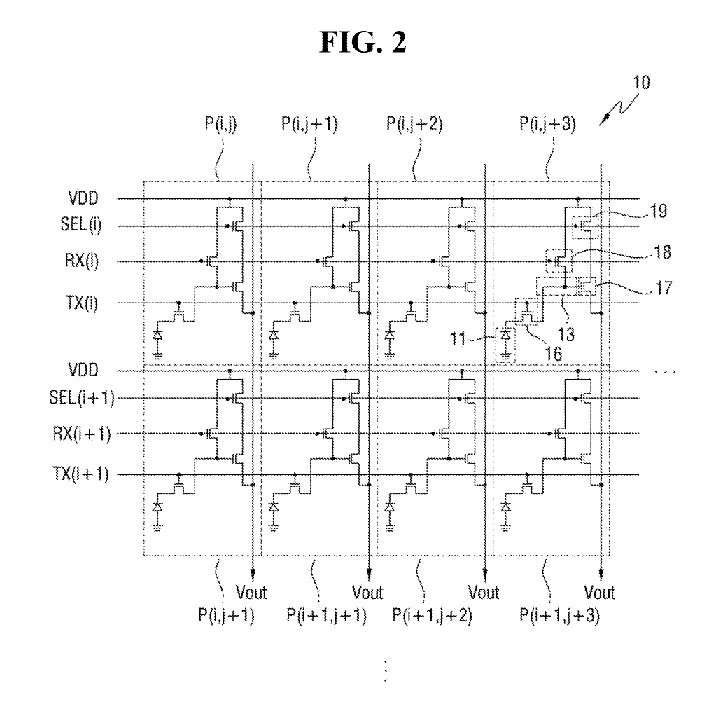

FIG. 1 is a block diagram of one embodiment of a semiconductor device 1 which includes an active pixel sensor (APS) array 10, a timing generator 20, an 12C interface 22, a control register block 24, a row driver 30, correlated double samplers (CDSs) 50a and 50b, an analog to digital converters (ADCs) 60a and 60b, latch units 70a and 70b, an internal voltage generator 80, and pads 15. The APS array 10 includes a plurality of pixels arranged in a matrix form. The pixels serve to convert an optical image into electrical signals. The APS array 10 is driven by receiving a plurality of driving signals such as a pixel selection signal (SEL), reset signal (RX), and charge transmission signal (TX) from the row driver 30. A detailed explanation of the configuration and operation of the APS array 10 is provided below with reference to FIG. 2.

The timing generator 20 receives a plurality of signals MCLK, RSTN, STBY, VSYNC, HSYNC, STRB and the like from an external source through the pads 15, and provides a control signal to the row driver 30 and the like at an appropriate timing. Here, MCLK means a main clock, and RSTN means a master reset signal. Further, STBY represents a standby mode signal, VSYNC represents a vertical sync signal, HSYNC represents a horizontal sync signal, and STRB represents a strobe signal for single frame capture. The signals presented in FIG. 1 are merely exemplary.

In an image sensor shown in FIG. 1, the I2C interface 22 may be used. The I2C interface 22 receives bi-directional data (SDA) and a clock (SCL).

The electrical signals converted in the pixels of the APS array 10 are provided to the correlated double samplers 50a and 50b through vertical signal lines. In this embodiment, the correlated double samplers 50a and 50b are arranged to be separated on different sides of the APS array 10. More specifically, electrical signals converted by the pixels located in odd-numbered columns are transmitted to the correlated double sampler 50a arranged on one side, and the electrical signals converted by the pixels located in even-numbered columns are transmitted to the correlated double sampler 50b arranged on the other side.

Each of the correlated double samplers 50a and 50b holds and samples the electrical signals provided from the APS array 10. Each of the correlated double samplers 50a and 50b also double-samples a noise level and a signal level of the electrical signals and outputs a difference level corresponding to a difference between the noise level and the signal level.

The analog to digital converters 60a and 60b convert analog signals corresponding to respective ones of the difference levels into digital signals and outputs the digital signals. The latch units 80a and 80b latch respective ones of the digital signals and output the latched signals through the pads 15.

FIG. 2 is an equivalent circuit of the APS array of FIG. 1. Referring to FIG. 2, the pixels P are arranged in the matrix form to form the APS array 10. Each of the pixels P includes an photoelectric conversion element 11, a floating diffusion region 13, a charge transfer element 16, a drive element 17, a reset element 18, and a selection element 19. For their functions, the description will be made using pixels P(i, j), P(i, j+1), P(i, j+2), P(i, j+3), . . . of the i-th row as an example.

The photoelectric conversion element 11 absorbs incident light and stores charges corresponding to the amount of light. Examples of the photoelectric conversion element 11 include a photodiode, a photo transistor, a photo gate, a pinned photodiode, or a combination thereof. In the drawing, a photodiode is shown as an example.

The photoelectric conversion element 11 is coupled to the charge transfer element 15 which transfers the accumulated charges to the floating diffusion region 13. The floating diffusion region (FD) 13 serves as a region to convert the charges into a voltage and has a parasitic capacitance. The charges are stored in the FD region cumulatively.

The drive element 17 (e.g., a source follower amplifier) amplifies a change in electrical potential of the floating diffusion region 13 which receives the charges accumulated in the photoelectric conversion element 11. The amplified signal is output to an output line Vout.

The reset element 18 periodically resets the floating diffusion region 13. The reset element 18 may be formed, for example, of one MOS transistor which is driven by a bias provided by a reset line RX(i) applying a bias. When the reset element 18 is turned on by the bias provided by the reset line RX(i), an electrical potential (e.g., a power supply voltage VDD, which is provided to a drain of the reset element 18) is transmitted to the floating diffusion region 13.

The selection element 19 serves to select the pixels P to be read on a row-by-row basis. The selection element 19 may be formed of one MOS transistor which is driven by a bias provided by a row selection line SEL(i). When the selection element 19 is turned on by the bias provided by the row selection line SEL(i), an electrical potential, e.g., a ower supply voltage VDD, being provided to the drain of the selection element 19 is transmitted to a drain region of the drive element 17.

A transmission line TX(i) applying a bias to the charge transfer element 15, the reset line RX(i) applying a bias to the reset element 18, and the row selection line SEL(i) applying a bias to the selection element 19 may be arranged to extend in a row direction substantially in parallel to each other.

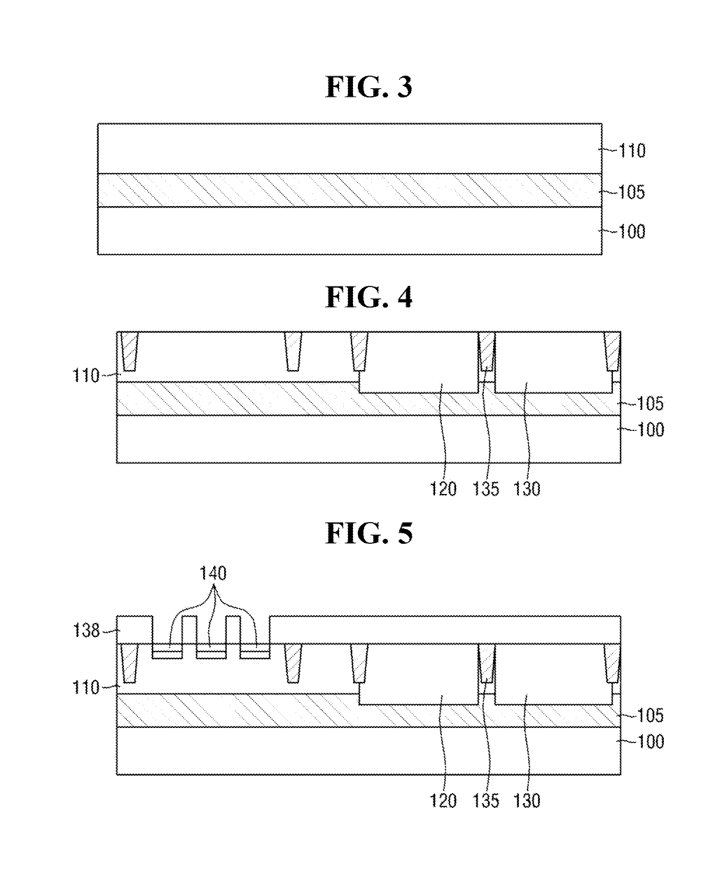

FIGS. 3-13 show operations included in an embodiment of a fabricating method of a semiconductor device. Referring to FIG. 3, a first conductivity type (e.g., P type) high concentration epitaxial layer 105 is formed on a substrate 100. The high concentration epitaxial layer 105 may be formed to have a thickness of, e.g., about 5 μm. The first conductivity type high concentration epitaxial layer 105 may be a deep well layer formed in order to reduce the resistance of the substrate.

Alternatively, the first conductivity type high concentration epitaxial layer 105 may be formed on a portion or the entire substrate of the substrate 100 by injecting P-type impurities such as In, B and Ga in a process of forming the epitaxial layer, or by ion implanting P-type impurities only in a necessary portion of the substrate 100 unlike the example shown in the drawing.

Subsequently, a first conductivity type low concentration epitaxial layer 110 is formed on the first conductive type high concentration epitaxial layer 105. The first conductivity type low concentration epitaxial layer 110 is a space in which a semiconductor device such as a well, photodiodes, device isolation film will be formed. For example, the first conductivity type low concentration epitaxial layer 110 may have a thickness of about 10 μm. The first conductivity type low concentration epitaxial layer 110 may have an impurity concentration smaller than that of the first conductivity type high concentration epitaxial layer 105.

The substrate 100 may be of a first conductivity type (e.g., P type), or a second conductivity type (e.g., N type). The substrate 100 may be, for example, a Si, SiGe, SOI (Silicon on Insulator) substrate or the like.

Referring to FIG. 4, in order to form a MOS transistor circuit in the first conductivity type low concentration epitaxial layer 110, different conductivity types of wells 120 and 130 may be formed. Further, a device isolation film 135 may be formed in a space in which wells 120 and 130 and a photodiode will be formed. The device isolation film 135 may be formed, e.g., by shallow trench isolation (STI).

Referring to FIG. 5, photodiodes 140 are formed. Specifically, a second conductivity type (e.g., N type) impurity layer and a first conductivity type (e.g., P type) impurity layer are formed vertically by using a mask pattern 138 to complete the photodiodes 140. When the photodiodes 140 are formed vertically in this manner, a depletion region is formed in a portion where the photodiodes 140 are in contact with the first conductive type low concentration epitaxial layer 110 so that the device can be operated. After forming the photodiodes 140, the mask pattern 138 is removed.

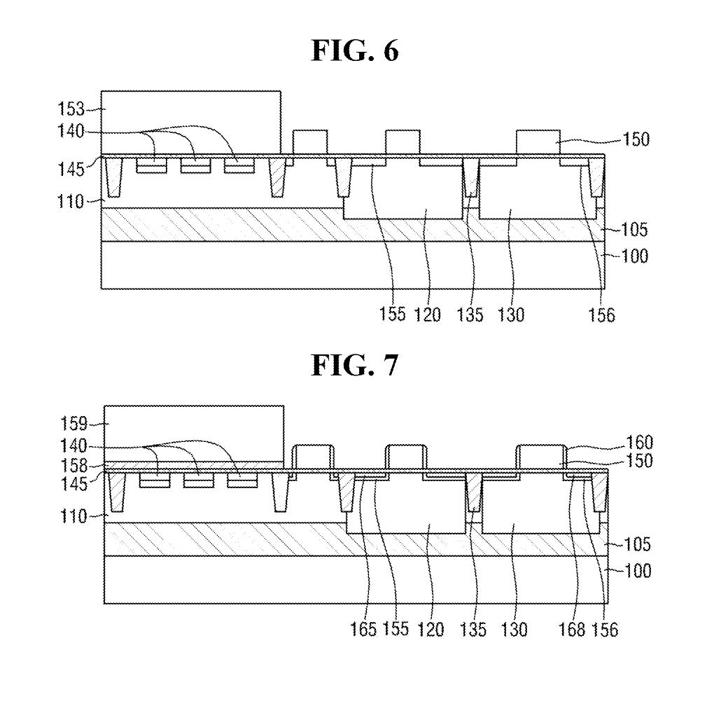

Referring to FIG. 6, a gate insulating film 145 is formed on an APS array region and peripheral circuit region and a gate electrode 150 is formed. Subsequently, a photoresist pattern 153 is formed in a region where the photodiodes 140 are formed. Then, a low concentration source/drain 155 and 156 is formed on respective sides of the gate electrode 150 by using the gate electrode 150 as a mask. After forming the low concentration source/drain 155 and 156, the mask pattern 153 is removed.

Referring to FIG. 7, a nitride film 158 is formed on a portion or the entire surface of the substrate 100, and a photoresist pattern 159 is formed in a region where the photodiodes 140 are formed. Then, the nitride film 158 is etched anisotropically by using the photoresist pattern 159, and a spacer 160 is formed in the vicinity of the gate electrode 150.

After forming the spacer 160, a second conductivity type (e.g., N type) high concentration source/drain 165 and a first conductivity type (e.g., P type) high concentration source/drain 168 are formed. After forming the high concentration source/drain 165 and 168, the photoresist pattern 159 is removed. The nitride film 158 may be removed selectively if necessary.

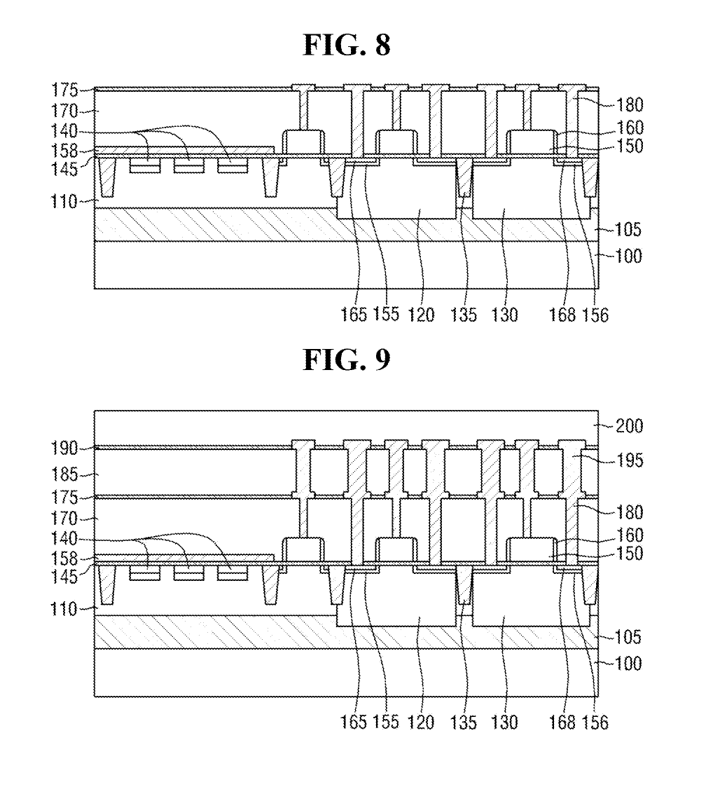

Referring to FIG. 8, a first interlayer insulating film 170 is formed on the substrate 100 on which the photodiodes 140 and the transistor are formed. The first interlayer insulating film 170 may be formed, for example, by HDP, CVD or the like, and an etch stop layer 175 is formed on the first interlayer insulating film 170. Then, a metal wiring (and /or metal plug) 180 is formed.

Referring to FIG. 9, a second interlayer insulating film 185 is formed on the etch stop layer 175. The second interlayer insulating film 185 may be formed by HDP, CVD or the like, and an etch stop layer 190 is formed on the second interlayer insulating film 185. Then, a metal wiring (and /or metal plug) 195 is formed. Then, a passivation film 200 is formed.

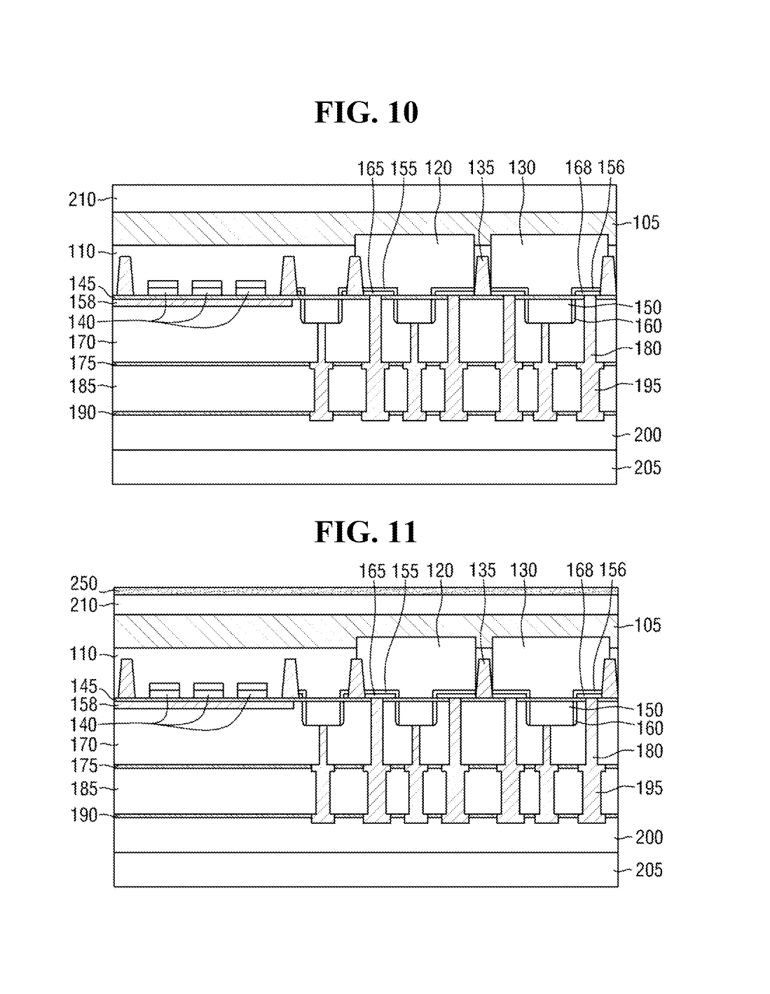

Referring to FIG. 10, a handling substrate 205 is attached onto the passivation film 200. After the handling substrate 205 is attached, the entire substrate 100 may be turned upside down such that the handling substrate 205 is located on the lower side.

Subsequently, the thickness of the substrate 100 is reduced by removing a portion of the other surface of the substrate 100. This is called a thinning process. The thinning process may include, e.g., at least one of mechanical grinding, polishing, CMP, wet etching or dry etching. In the drawing, reference numeral 210 indicates the substrate 100 on which the thinning process has been completed.

For illustrative purposes, a case of removing a portion of the other surface of the substrate 100 has been shown in the drawing. For example, the first conductivity type high concentration epitaxial layer 105 may be exposed by removing all of the substrate 100. Alternatively, a portion of the first conductivity type high concentration epitaxial layer 105 may also be removed.

Meanwhile, the other surface of the substrate 210 on which the thinning process has been completed may have defects of a very high level. The defects may include one or more of a surface defect, a sub-surface defect generated below the surface, or a deep-surface defect generated at the deepest place. Deep-surface defects, and especially those generated at a deepest point of the device, are hard to remove.

For example, even if it is intended to remove the deep-surface defect by using CMP, since the CMP itself can cause a fine defect, it is difficult to remove the deep-surface defect. Such defects may reduce the characteristics of the image sensor. In particular, the dark characteristics of the sensor may be degraded. Dark characteristics may include the formation of an unnecessary current (hereinafter, referred to as a dark current) which occurs in a black out state, abnormal pixels (hereinafter, referred to as white points) which are brighter than the surrounding pixels in the black out state, as well as other adverse defects.

Referring to FIG. 11, through an oxidation process, an oxide film 250 is formed on the other surface of the substrate 210 on which the thinning process has been completed. The oxide film 250 may include at least one of a hafnium oxide film, an aluminum oxide film, a zirconium oxide film, a tantalum oxide film, a titan oxide film, a ruthenium oxide film, an iridium oxide film, a yttrium oxide film, or an oxynitride film.

In accordance with one embodiment, a low-temperature oxidation process may be used to form the oxide film 250. Low-temperature oxidation refers to a reaction between a solid and a gas occurring below a certain threshold temperature. The reaction may involve the combination of oxygen with a material to form an oxide layer (in this case, to form oxide film 250 to a depth in the other surface of substrate 210).

The threshold temperature for the reaction, for example, may be below a temperature at which the metal used to form the metal wiring or metal layers of the device melt. One reason for using low-temperature oxidation is that there is a limitation in raising the temperature of the substrate 210 because metal wirings 180 and 195 are formed on one surface of the substrate 210. In other embodiments, a lesser or greater temperature range may be used for the oxidation process.

The oxide film 250 may be formed to a depth at which the defect of the substrate 210 is formed. For example, the thickness of the oxide film 250 may range from 50 Å to 150 Å. In this case, the thickness of the oxide film 250 may be changed depending on the level of the defect formed on the other surface of the substrate 210.

If the thickness of the oxide film 250 is smaller than 50 Å, the oxide film 250 may not be formed to a depth at which the defect of the substrate 210 is formed (i.e., portion in which the deep-surface defect is located). If the thickness of the oxide film 250 is greater than 150 Å, the oxide film 250 may be formed to be unnecessarily thick. For example, the thickness of the oxide film 250 may be about 100 Å.

In this case, low-temperature oxidation may include low-temperature oxidation using a plasma. The low-temperature oxidation may use oxygen or ozone radicals. Alternatively, oxidation may be performed using chemicals. However, it may be more difficult to thickly form the oxide film 250 in this manner. For example, it is possible to form an oxide film of about 20 Å using the oxidation using chemicals. Accordingly, it may be difficult to form the oxide film to a portion where the defect is located deeply in the substrate 210. Nevertheless, this approach may also be taken.

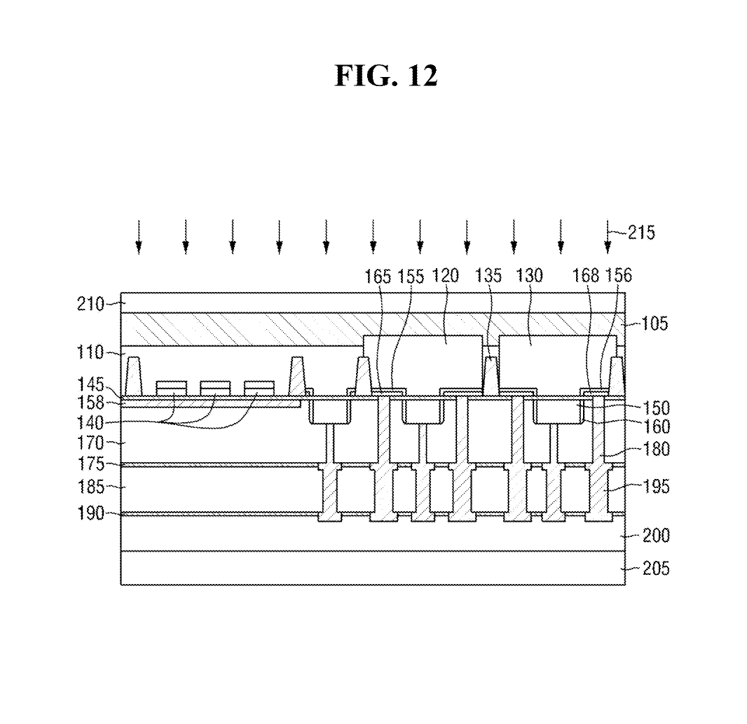

Referring to FIG. 12, the oxide film 250 formed on the other surface of the substrate 210 is removed. For example, the oxide film 250 may be removed by an etching process 215. That is, the oxide film 250 may be removed by wet etching, dry etching, or a combination of wet etching and dry etching. By removing the oxide film 250 in this way, the defect located on the other surface of the substrate 210 can be removed simultaneously.

According to one or more embodiments of the fabricating method of a semiconductor device, defects located deeply in the substrate 210 may be removed by forming the oxide film 250 on the other surface of the substrate 210 through low-temperature oxidation and removing the oxide film 250. Thus, the dark characteristics such as dark current and white points can be improved sufficiently.

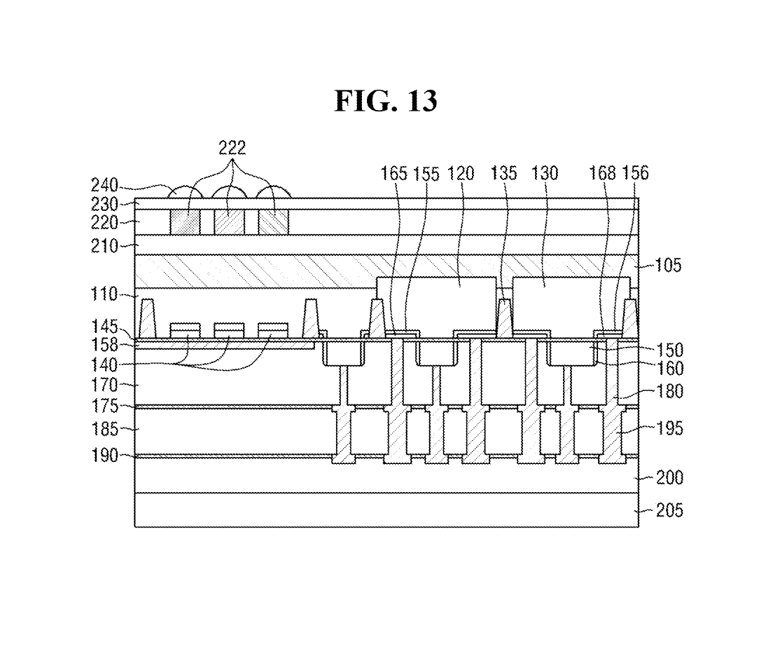

Referring to FIG. 13, impurities for preventing the dark current may be injected into the other surface of the substrate 210, and low-temperature annealing may be performed to activate the impurities. Then, color filters 222 of red/green/blue and a shading insulating film 220 are formed on the substrate 210.

A planarization layer 230 is formed on the color filters 222 and the shading insulating film 220, and microlenses 240 are formed on the color filters 222. Of the light passing through the microlenses 240, chromatic light of a certain type is selected by the color filters 222, and the selected chromatic light is accumulated in the underlying photodiodes 140.

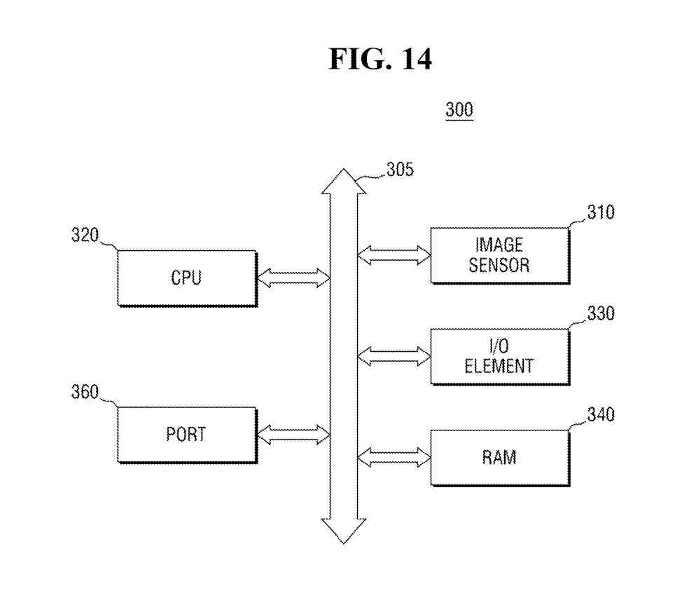

FIG. 14 is a schematic block diagram showing an embodiment of a processor-based system 300 that includes the semiconductor device fabricated using any of the foregoing embodiments of the fabricating method.

Referring to FIG. 14, the processor-based system 300 may be a system which processes an output image of a MOS image sensor 310. Examples of the system 300 include a computer system, camera system, scanner, mechanized clock system, navigation system, videophone, supervision system, automatic focusing system, tracking system, operation monitoring system, image stabilization system, tablet PC, laptop, mobile phone and the like.

When the processor-based system 300 is a computer system, the processor-based system 300 may include a central processing unit (CPU) 320 (e.g., a microprocessor) communicating with an input/output (I/O) element 330 through a bus 305. The MOS image sensor 310 may communicate with various parts of the system through the bus 305 or another communication link.

The processor-based system 300 may further include a RAM 340 and/or a port 360 that may communicate with the CPU 320 through the bus 305. The port 360 may be a port capable of coupling, for example, a video card, a sound card, a memory card, or a USB device to the processor-based system 300 and/or may perform data communications with another system. The MOS image sensor 310 may be integrated with the CPU, a digital signal processor (DSP), or a microprocessor. Alternatively, the MOS image sensor 310 may be integrated with a memory or, in some cases, may be integrated on a chip separate from the processor.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A fabricating method of a semiconductor device, comprising:
forming wiring on a first surface of a first substrate;
removing a portion of a second surface of the first substrate to reduce a thickness of the first substrate;
forming an oxide film on the second surface of the first substrate based on an oxidation process performed within a temperature range; and
removing the oxide film.

2. The method of claim 1, wherein the temperature range is below a melting temperature of the wiring.

3. The method of claim 1, wherein forming the oxide film includes:
forming the oxide film to a depth that includes one or more defects below the second surface of the first substrate, wherein removing the oxide film includes removes a portion of the first substrate that includes the one or more defects.

4. The method of claim 1, wherein the oxidation process is performed using a plasma.

5. The method of claim 1, wherein the oxidation process is performed using oxygen or ozone radicals.

6. The method of claim 1, wherein the oxide film includes at least one of a hafnium oxide film, an aluminum oxide film, a zirconium oxide film, a tantalum oxide film, a titan oxide film, a ruthenium oxide film, an iridium oxide film, a yttrium oxide film, or an oxynitride film.

7. The method of claim 3, wherein the oxide film is formed to a depth ranging substantially from 50 Å to 150 Å.

8. The method of claim 1, further comprising:
attaching the first substrate to a second substrate before removing a portion of the second surface of the first substrate.

9. The method of claim 1, wherein the removing a portion of the second surface of the first substrate comprises at least one of mechanical grinding, polishing, CMP, wet etching or dry etching.

10. The method of claim 1, wherein the removing the oxide film comprises removing the oxide film through an etching process.

11. The method of claim 1, further comprising:
after removing the oxide film, injecting impurities into the second surface of the first substrate, and performing an annealing operation to activate the impurities, wherein the impurities are of a type for preventing flow of a dark current.

12. The method of claim 1, further comprising:
forming one or more photodiodes facing the first surface of the first substrate, wherein the first substrate is a transparent substrate to allow light to pass to the one or more photodiodes.

13. The method of claim 1, further comprising:
forming one or more microlenses over the second surface of the first substrate, wherein the one or more microlenses are in substantial alignment with respective ones of the one or more photodiodes.

14. The method of claim 13, further comprising:
forming one or more color filters over the second surface of the first substrate, wherein the one or more color filters are located between the one or more microlenses and the one or more photodiodes.

15. A method of making a semiconductor device, comprising:
forming wiring on a first surface of a substrate;
removing a portion of a second surface of the substrate to reduce a thickness of the substrate;
forming a hafnium oxide film on the second surface of the substrate based on an oxidation process using a plasma; and
removing the hafnium oxide film based on an etching process.

16. The method of claim 15, wherein the oxidation process is performed using oxygen or ozone radicals.

17. The method of claim 15, wherein the hafnium oxide film is formed to a depth ranging substantially from 50 Å to 150 Å, and wherein said depth includes one or more defects under the second surface of the substrate.

18. The method of claim 15, wherein said removing a portion of the second surface of the substrate comprises at least one of mechanical grinding, polishing, CMP, wet etching or dry etching.

19. The method of claim 15, further comprising:
after removing the hafnium oxide film, injecting impurities into the second surface of the substrate, and
performing an annealing operation to activate the impurities, wherein the impurities are of a type for preventing flow of a dark current.

20. The method of claim 15, further comprising:
forming a photodiode facing the first surface of the substrate, and
forming a microlens over the second surface of the substrate, wherein the substrate is a transparent substrate to allow light to pass to the photodiode and wherein the microlens is in substantial alignment with the one or more photodiode.
